(19) United States
(12) Patent Application Publication
(10) Pub. No.: US 2026/0334284 A1
(43) Pub. Date: Oct. 22, 2026

(54) SEMICONDUCTOR DEVICE INCLUDING INSULATING LAYERS AND METHOD FOR MANUFACTURING THE SAME

(71) Applicant: Samsung Electronics Co., Ltd., Suwon-si (KR)

(72) Inventors: Minho JANG, Suwon-si (KR); Doyeon KIM, Suwon-si (KR); Jiyeong KIM, Suwon-si (KR); Sungmin SON, Suwon-si (KR); Yongkun JO, Suwon-si (KR)

(73) Assignee: Samsung Electronics Co., Ltd., Suwon-si (KR)

(21) Appl. No.: 19/540,965

(22) Filed: Feb. 16, 2026

(30) Foreign Application Priority Data
Apr. 16, 2025 (KR) 10-2025-0049626

(51) Int. Cl. H10W 72/90; H10F 39/95; H10W 90/00; H10W 90/20

(52) U.S. Cl. CPC H10W 72/967; H10W 72/934; H10W 72/936; H10W 72/9445; H10W 72/963; H10W 90/792; H10F 39/95; H10W 90/20

(57) ABSTRACT

A semiconductor device may include a first substrate including a first region and a second region, a first insulating layer on the first substrate, the first insulating layer having a first surface and a second surface, the first surface being adjacent to the first substrate and the second surface being opposite the first surface, the first insulating layer including a first trench on the first region and a first recess on the second region, the first recess being recessed from the second surface of the first insulating layer, a first insulating liner layer on the second surface of the first insulating layer, the first insulating liner layer extending onto an inner surface of the first recess, and a first bonding pattern in the first trench.

### CROSS-REFERENCE TO RELATED APPLICATIONS

This application claims priority under 35 U.S.C. § 119 to Korean Patent Application No. 10-2025-0049626 filed on Apr. 16, 2025, in the Korean Intellectual Property Office, the disclosures of which are incorporated by reference herein in their entireties.

### BACKGROUND

Some example embodiments of the present disclosure described herein relate to semiconductor devices and/or manufacturing methods thereof.

A semiconductor device may be manufactured through various processes. For example, the semiconductor device may be manufactured through a photoresist process, an etching process, a deposition process, a heat treatment process, and/or a test process. In addition, a bonding process of bonding substrates to each other may be performed. Before two substrates are bonded to each other, surfaces of the substrates may be processed. For example, a planarization process may be performed after metal materials and insulating materials are deposited on the surfaces of the substrates.

Meanwhile, due to a difference in removal rate between the metal materials and the insulating materials, a step may occur in the planarization process, which may cause relatively poor bonding of the substrates. Accordingly, a technical improvement for improving the flatness of a bonding portion is desired.

### SUMMARY

Some example embodiments of the present disclosure provide semiconductor devices with improved flatness of a bonding portion.

Some example embodiments of the present disclosure provide semiconductor devices manufacturing method with improved accuracy of a bonding process.

According to an example embodiment, a semiconductor device includes a first substrate including a first region and a second region, a first insulating layer on the first substrate, the first insulating layer having a first surface and a second surface, the first surface being adjacent to the first substrate and the second surface being opposite the first surface, the first insulating layer including a first trench on the first region and a first recess on the second region, the first recess being recessed from the second surface of the first insulating layer, a first insulating liner layer on the second surface of the first insulating layer, the first insulating liner layer extending onto an inner surface of the first recess, and a first bonding pattern in the first trench.

According to an example embodiment, a semiconductor device includes a first substrate including a first region and a second region, a first insulating layer on the first substrate, the first insulating layer having a first surface and a second surface, the first surface being adjacent to the first substrate and the second surface being opposite the first surface, the first insulating layer including a first trench on the first region and a first recess on the second region, the first recess being recessed on the second region from the second surface of the first insulating layer, a first insulating liner layer on the second surface of the first insulating layer, the first insulating liner layer extending onto an inner surface of the first recess, a first bonding pattern in the first trench, a second substrate, a second insulating layer on the second substrate, the second insulating layer having a third surface and a fourth surface, the third surface being adjacent to the second substrate and the fourth surface being opposite the third surface, the second insulating layer including a second trench and a second recess, the second recess being recessed from the fourth surface of the second insulating layer, a third insulating liner layer on the fourth surface of the second insulating layer, the third insulating liner layer extending onto an inner surface of the second recess, and a second bonding pattern in the second trench, wherein the first bonding pattern and the second bonding pattern are bonded to each other, and the first insulating liner layer and the third insulating liner layer are bonded to each other.

According to an example embodiment, a semiconductor device includes a first structure, and a second structure bonded to the first structure, wherein the first structure includes a first substrate including a pixel array region, a pad region on one side of the pixel array region, and an optical black region between the pixel array region and the pad region, a first bonding pattern vertically overlapping the pixel array region, the first bonding pattern being in a first trench defined in a first insulating layer, and a first dummy pattern vertically overlapping at least one of the optical black region or the pad region, and the second structure includes a second substrate, a second bonding pattern bonded to the first bonding pattern, and a second dummy pattern bonded to the first dummy pattern.

### BRIEF DESCRIPTION OF THE DRAWINGS

The above and other objects and features of the present disclosure will become apparent by describing in detail some example embodiments thereof with reference to the accompanying drawings.

FIG. 1 is a sectional view of a semiconductor device according to an example embodiment of the present disclosure.

FIG. 2 is a plan view of the semiconductor device according to an example embodiment of the present disclosure.

FIG. 3 is a sectional view taken along line A-A′ of FIG. 2.

FIG. 4 is a plan view of a semiconductor device according to an example embodiment of the present disclosure.

FIG. 5 is a sectional view taken along line A-A′ of FIG. 4.

FIG. 6 is a plan view of a semiconductor device according to an example embodiment of the present disclosure.

FIG. 7 is a sectional view taken along line A-A′ of FIG. 6.

FIG. 8 is a sectional view of a semiconductor device according to an example embodiment of the present disclosure.

FIG. 9 is a sectional view of a semiconductor device according to an example embodiment of the present disclosure.

FIG. 10 is a sectional view of a semiconductor device according to an example embodiment of the present disclosure.

FIG. 11 is a sectional view of a semiconductor device according to an embodiment of the present disclosure.

FIG. 12 is a sectional view of a semiconductor device according to an example embodiment of the present disclosure.

FIG. 13 is a plan view of a semiconductor device according to an example embodiment of the present disclosure.

FIGS. 14A to 14E are sectional views illustrating a semiconductor device manufacturing method according to an example embodiment of the present disclosure.

FIGS. 15A to 15D are sectional views illustrating a semiconductor device manufacturing method according to an example embodiment of the present disclosure.

FIGS. 16A to 16D are sectional views illustrating a semiconductor device manufacturing method according to an example embodiment of the present disclosure.

### DETAILED DESCRIPTION

Hereinafter, some example embodiments of the present disclosure will be described in more detail with reference to the accompanying drawings.

As used herein, expressions such as “one of,” “one or more of,” “any one of,” “at least one of,” “at least one among” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

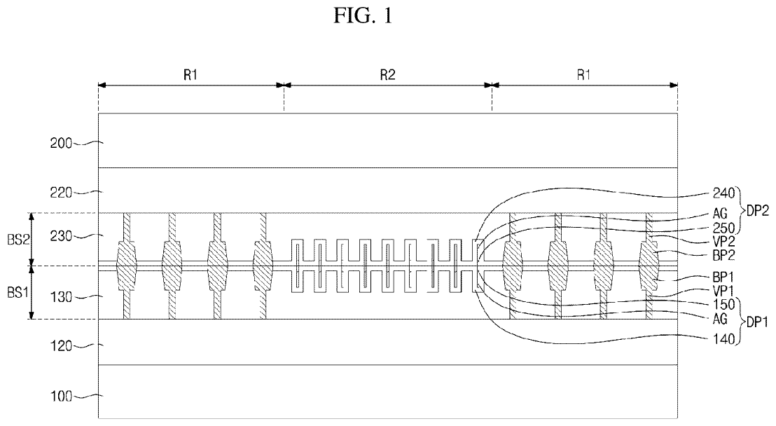

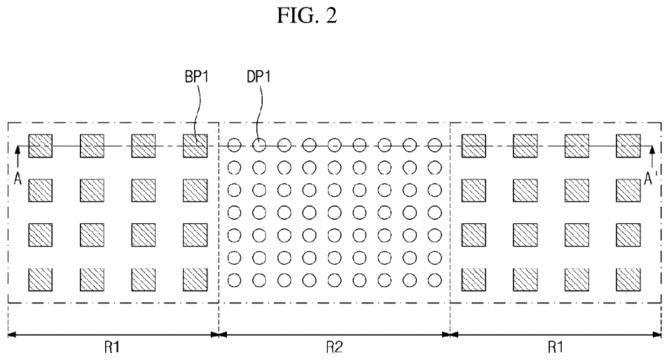

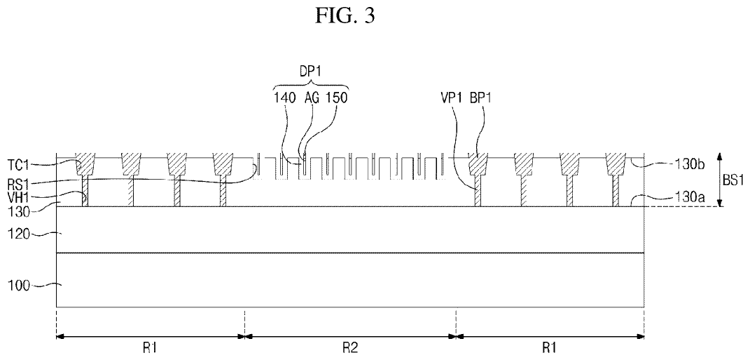

FIG. 1 is a sectional view of a semiconductor device according to an example embodiment of the present disclosure. FIG. 2 is a plan view of the semiconductor device according to an example embodiment of the present disclosure. FIG. 3 is a sectional view taken along line A-A′ of FIG. 2.

Referring to FIGS. 1 to 3, the semiconductor device according to an example embodiment of the present disclosure may include a first substrate 100, a second substrate 200, a first device layer 120, a second device layer 220, a first insulating layer 130, a second insulating layer 230, a first bonding pattern BP1, a second bonding pattern BP2, a first insulating liner layer 140, a second insulating liner layer 150, a third insulating liner layer 240, and a fourth insulating liner layer 250.

More specifically, the semiconductor device according to an example embodiment of the present disclosure may have a chip to chip (C2C) structure in which the first substrate 100 and the second substrate 200 are bonded to each other. The C2C structure may mean connecting at least one upper substrate and at least one lower substrate to each other by a bonding method. In an example embodiment, the bonding method may mean a method of electrically or physically connecting the first bonding pattern BP1 of the first substrate 100 and the second bonding pattern BP2 of the second substrate 200 to each other. For example, when the first bonding pattern BP1 and the second bonding pattern BP2 are formed of copper (Cu), the bonding method may be a Cu—Cu bonding method.

In an example embodiment, the second substrate 200, the second device layer 220, the second insulating layer 230, the second bonding pattern BP2, the third insulating liner layer 240, and the fourth insulating liner layer 250 have substantially the same structures, materials, and shapes as the first substrate 100, the first device layer 120, the first insulating layer 130, the first bonding pattern BP1, the first insulating liner layer 140, and the second insulating liner layer 150, respectively. Therefore, the first substrate 100, the first device layer 120, the first insulating layer 130, the first bonding pattern BP1, the first insulating liner layer 140, and the second insulating liner layer 150 will hereinafter be described in detail.

The first substrate 100 may include a first region R1 and a second region R2. The first region R1 may be a region within the first substrate 100 where the first bonding pattern BP1 is provided, and the second region R2 may be a region within the first substrate 100 where a first dummy pattern DP1 is provided.

The first substrate 100 may include a silicon on insulator (SOI) substrate, a metal substrate, a glass substrate, or a plastic substrate, as well as a semiconductor substrate formed of a semiconductor material. The semiconductor substrate may be, for example, a silicon substrate, a germanium substrate, or a silicon-germanium substrate.

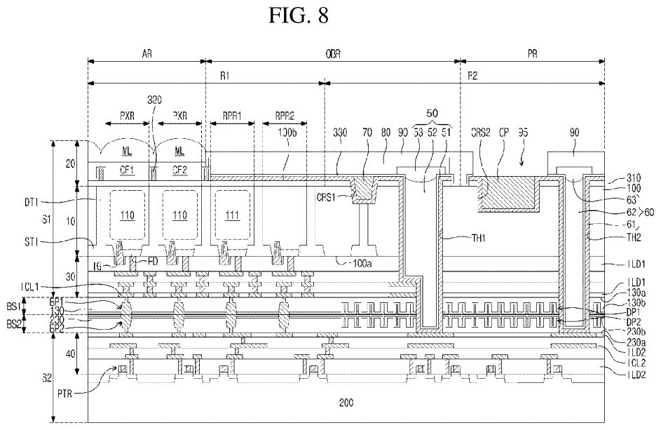

The first device layer 120 may be provided on the first substrate 100. In this specification, the first device layer 120 may refer to one structure of various types of semiconductor devices. For example, the first device layer 120 may correspond to a circuit wiring layer 30 (refer to FIG. 8) of an image sensor illustrated in FIG. 8. The structure, shape, and/or constituent material of the first device layer 120 may vary depending on the type of semiconductor device.

The first insulating layer 130 may be provided on the first substrate 100. The first insulating layer 130 may have a first surface 130a and a second surface 130b. The first surface 130a may be a surface adjacent to the first substrate 100. The second surface 130b may be a surface opposite the first surface 130a.

The first insulating layer 130 may include an insulating material. The first insulating layer 130 may include, for example, silicon oxide (SiOₓ).

The first insulating layer 130 may have a first trench TC1 and a first recess RS1. The first trench TC1 may be formed from the second surface 130b of the first insulating layer 130 on the first region R1. The first recess RS1 may be recessed from the second surface 130b of the first insulating layer 130 on the second region R2.

In an example embodiment, the width of the bottom surface of the first trench TC1 may be greater than or substantially the same as the width of the bottom surface of the first recess RS1. In addition, the level of the bottom surface of the first trench TC1 may be higher than or substantially the same as the level of the bottom surface of the first recess RS2.

The first insulating liner layer 140 may be provided on the second surface 130b of the first insulating layer 130. The first insulating liner layer 140 may extend onto the inner surface of the first recess RS1. The first insulating liner layer 140, when viewed in a plan view, may cover the remaining region of the second surface 130b of the first insulating layer 130 other than the region corresponding to the inner surface of the first trench TC1.

The first insulating liner layer 140 may have a uniform thickness. In contrast, depending on a process method, the first insulating liner layer 140 may have different thicknesses for respective regions. For example, the thickness of the first insulating liner layer 140 formed on the inner surface of the first recess RS1 may be smaller than the thickness of the first insulating liner layer 140 formed on a region of the second surface 130b of the first insulating layer 130 other than the inner surface of the first recess RS1.

The first insulating liner layer 140 may include a material having a lower removal rate than the first bonding pattern BP1. The first insulating liner layer 140 may include, for example, silicon oxide (SiOₓ), silicon nitride (SiNₓ), silicon oxy nitride (SiOₓN_{y}), silicon carbon nitride (SiCₓN_{y}), or a combination thereof.

The second insulating liner layer 150 may be disposed on the first insulating liner layer 140. The second insulating liner layer 150 may fill the inner surface of the first recess RS1. The second insulating liner layer 150 may close the first recess RS1.

The second insulating liner layer 150 may include a material having a higher removal rate than the first insulating liner layer 140. The second insulating liner layer 150 may include, for example, silicon oxide (SiₓO_{y}).

In an example embodiment, an air gap AG may be defined in the first recess RS1.

The air gap AG may be defined in an empty space between the first insulating liner layer 140 and the second insulating liner layer 150. For example, the air gap AG may be surrounded by the first insulating liner layer 140 in the first recess RS1 and the upper end of the air gap AG may be sealed by the second insulating liner layer 150. In other words, lower and side boundaries of the air gap AG may be surrounded by the fist insulating liner layer 140 and an upper boundary of the air gap AG may be sealed by the second insulating liner layer 150.

In an example embodiment, the first insulating liner layer 140, the second insulating liner layer 150, and the air gap AG in the first recess RS1 may form the first dummy pattern DP1. The first dummy pattern DP1 may be provided on the second region R2 of the first substrate 100.

In an example embodiment, the second insulating liner layer 150 may be omitted. In this case, the first insulating liner layer 140 may fill the first recess RS1. For example, the first insulating liner layer 140 may completely fill the inner space of the first recess RS1. In this case, the formation of the air gap AG may be omitted. In some example embodiments, the first insulating liner layer 140 may surround the inner space of the first recess RS1 and may define the air gap AG.

In an example embodiment, the second insulating liner layer 150 may completely cover the upper surface of the first insulating liner layer 140. In this case, the air gap AG may be omitted. For example, the second insulating liner layer 150 and the first insulating liner layer 140 may completely fill the inner space of the first recess RS1.

The first bonding pattern BP1 may be provided in the first trench TC1. The first bonding pattern BP1 may fill the inside of the first trench TC1. The first bonding pattern BP1 may penetrate the first insulating liner layer 140. In other words, the first trench TC1 may vertically extend to penetrate the first insulating liner layer 140.

In an example embodiment, the level of the upper surface of the first bonding pattern BP1 and the level of the upper surface of the first insulating liner layer 140 may be substantially the same as each other. In addition, the level of the bottom surface of the first bonding pattern BP1 may be higher than or substantially the same as the level of the bottom surface of the first recess RS1.

The first bonding pattern BP1 may be provided in plural on the first region R1 when viewed in a plan view. In other words, the first bonding pattern BP1 may include a plurality of first bonding patterns BP1 on the first region R1 when viewed in a plan view. For example, the first bonding patterns BP1 may be arranged in one or two directions parallel to the second surface 130b of the first insulating layer 130 when viewed in a plan view. For example, as illustrated in FIG. 2, the first bonding patterns BP1 may be disposed in a 4×4 matrix when viewed in a plan view.

The first bonding pattern BP1 may include a conductive material. The first bonding pattern BP1 may include, for example, copper (Cu), tungsten (W), aluminum (Al), or a combination thereof. When the first bonding pattern BP1 and the second bonding pattern BP2 are formed of or include copper (Cu), the first substrate 100 and the second substrate 200 of the semiconductor device may be bonded to each other by a Cu—Cu bonding method.

A first via pattern VP1 may be provided in a first via hole VH1. The first via hole VH1 may be defined in the first insulating layer 130. The first via hole VH1 may extend from the bottom surface of the first trench TC1 to the upper surface of the first device layer 120. In other words, the first via hole VH1 may be connected with the bottom surface of the first trench TC1 and the first device layer 120.

The first via pattern VP1 may fill the inside of the first via hole VH1. The first via pattern VP1 may be connected to the lower surface of the first bonding pattern BP1. The first via pattern VP1 may electrically connect the first bonding pattern BP1 and the first device layer 120.

The first via pattern VP1 may include a conductive material. The first via pattern VP1 may include, for example, copper (Cu), tungsten (W), aluminum (Al), or a combination thereof.

In an example embodiment, as illustrated in FIG. 1, the first insulating layer 130, the first bonding pattern BP1, the first insulating liner layer 140, and the second insulating liner layer 150 may constitute a first bonding structure BS1. Here, the second insulating liner layer 150 may be omitted. In addition, the second insulating layer 230, the second bonding pattern BP2, the third insulating liner layer 240, and the fourth insulating liner layer 250 may constitute a second bonding structure BS2. Here, the fourth insulating liner layer 250 may be omitted.

In an example embodiment, the first bonding structure BS1 and the second bonding structure BS2 may be bonded to each other. More specifically, the first bonding pattern BP1 and the second bonding pattern BP2 may be bonded to each other. The first insulating liner layer 140 and the third insulating liner layer 240 may be bonded to each other.

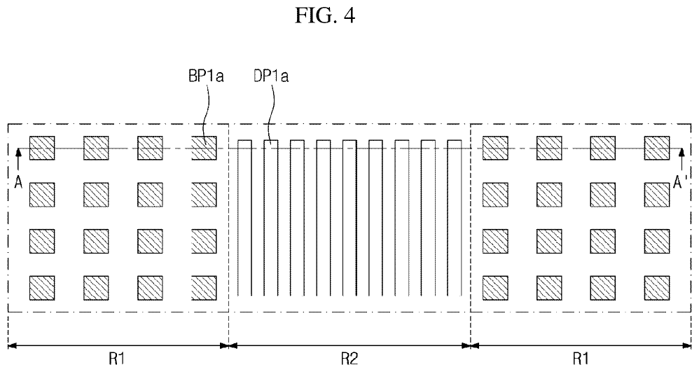

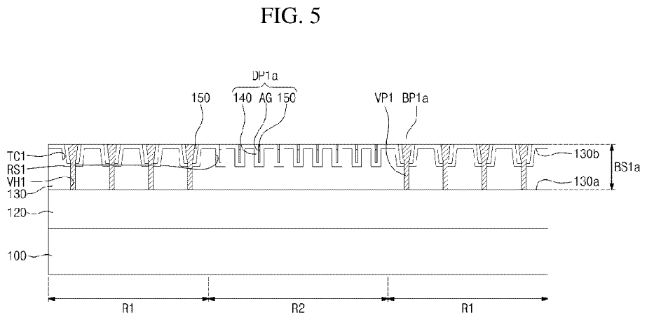

FIG. 4 is a plan view of a semiconductor device according to an example embodiment of the present disclosure. FIG. 5 is a sectional view taken along line A-A′ of FIG. 4. For convenience of description, the following description will be focused on differences from the above-described example embodiments.

Referring to FIGS. 4 and 5, a plurality of first recesses RS1 may be provided together with a plurality of first trenches TC1. The first recesses RS1 may be arranged in one or two directions parallel to a second surface 130b of a first insulating layer 130 when viewed in a plan view.

The first recess RS1 may have various shapes. The first recess RS1 may have, for example, a circular shape, an elliptical shape, a polygonal shape, or a line shape when viewed from above the plan. For example, the first recess RS1 may have a circular shape when viewed in a plan view. For example, as illustrated in FIG. 4, the first recess RS1 may have a line shape when viewed in a plan view.

Accordingly, a first dummy pattern (DP1 or DP1a) may also have various shapes. For example, as illustrated in FIG. 2, the first dummy pattern DP1 may have a circular shape when viewed in a plan view. For example, as illustrated in FIG. 4, the first dummy pattern DP1a may have a line shape when viewed in a plan view.

In an example embodiment, a first bonding pattern BP1a may have various structures. For example, unlike that illustrated in FIG. 3, a first insulating liner layer 140 may extend to cover the inner surface of the first trench TC1. In addition, a second insulating liner layer 150 may extend to cover the upper surface of the first insulating liner layer 140. In other words, the second insulating liner layer 150 may extend to cover a recess defined by the upper surface of the first insulating liner layer 140.

The first bonding pattern BP1a may penetrate the first insulating liner layer 140 and the second insulating liner layer 150 on the bottom surface of the first trench TC1. In other words, the first bonding pattern BP1a may have a structure that penetrates the first insulating liner layer 140 and the second insulating liner layer 150 in the first trench TC1.

As illustrated in FIG. 5, the first insulating layer 130, the first bonding pattern BP1a, the first insulating liner layer 140, and the second insulating liner layer 150 may constitute a first bonding structure BS1a.

In an example embodiment, unlike in FIG. 5, the formation of the second insulating liner layer 150 may be omitted. For example, the first insulating liner layer 140 may be formed on the inner surface of the first trench TC1. For example, the first bonding pattern BP1a may have a structure that penetrates the first insulating liner layer 140 in the first trench TC1. In addition, the first insulating liner layer 140 may fill the inside of the first recess RS1. Accordingly, the first insulating liner layer 140 may constitute the first dummy pattern DP1a. In this case, the first insulating layer 130, the first bonding pattern DP1a, and the first insulating liner layer 140 may constitute the first bonding structure BS1a.

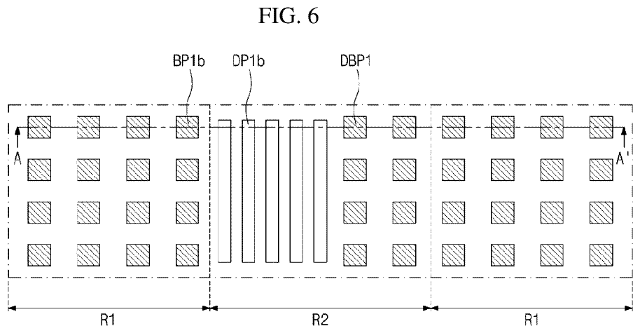

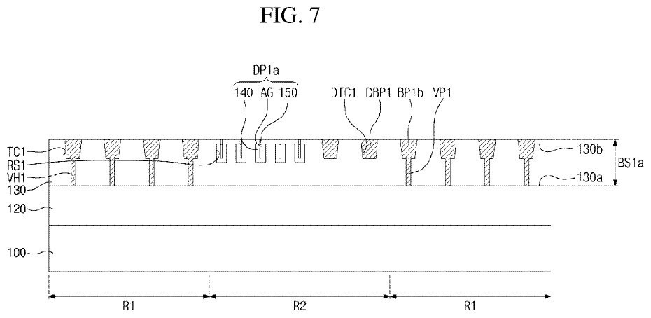

FIG. 6 is a plan view of a semiconductor device according to an example embodiment of the present disclosure. FIG. 7 is a sectional view taken along line A-A′ of FIG. 6. For convenience of description, the following description will be focused on differences from the above-described example embodiments.

Referring to FIGS. 6 and 7, the semiconductor device according to an example embodiment of the present disclosure may further include a first dummy bonding pattern DBP1. The first dummy bonding pattern DBP1 may be provided in a first dummy trench DTC1. The first dummy trench DTC1 may be formed in a first insulating layer 130 on a second region R2. The first dummy trench DTC1 may have substantially the same shape and/or structure as a first trench TC1.

The first dummy bonding pattern DBP1 may be provided in plural on the second region R2 when viewed in a plan view. For example, the first dummy bonding patterns DBP1 may be arranged in one or two directions parallel to a second surface 130b of the first insulating layer 130 when viewed in a plan view. For example, as illustrated in FIG. 6, the first dummy bonding patterns DBP1 may be disposed in a 4×2 matrix when viewed in a plan view.

The first dummy bonding pattern DBP1 may include a conductive material. The first dummy bonding pattern DBP1 may include, for example, copper (Cu), tungsten (W), aluminum (Al), or a combination thereof. In an example embodiment, the first dummy bonding structure DBP1 may be formed of or include the same material as the first bonding pattern BP1b.

Meanwhile, the semiconductor device according to an example embodiment of the present disclosure may be various types of semiconductor devices. For example, the semiconductor device may be a volatile memory device, such as a complementary metal oxide semiconductor (CMOS) type image sensor, DRAM, DRAM Vertical Channel Transistor (DRAM VCT), synchronous DRAM (SDRAM), double data rate SDRAM (DDR SDRAM), low power double data rate SDRAM (LPDDR SDRAM), graphics double data rate SDRAM (GDDR SDRAM), DDR2 SDRAM, DDR3 SDRAM, DDR4 SDRAM, or thyristor RAM (TRAM), or a nonvolatile memory device, such as phase change random access memory (PRAM), magnetic random access memory (MRAM), resistive random access memory (RRAM), or vertical NAND (VNAND) flash memory. Hereinafter, some example embodiments in which a device layer 120 of a semiconductor device according to an example embodiment of the present disclosure is a complementary metal oxide semiconductor (CMOS) type image sensor, a DRAM including a vertical channel transistor structure, and a VNAND will be described.

FIG. 8 is a sectional view of a semiconductor device according to an example embodiment of the present disclosure. For convenience of description, the following description will be focused on differences from the above-described example embodiments.

Referring to FIG. 8, the semiconductor device according to an example embodiment of the present disclosure may be a CMOS type image sensor. The image sensor may include a first structure S1 and a second structure S2. The first structure S1 may be stacked on the second structure S2. That is, the image sensor may have a stacked structure. The first structure S1 may be referred to as a sensor chip or a first chip. The second structure S2 may be referred to as a logic chip or a second chip. In an example embodiment, a first bonding structure BS1 may be provided on the first structure S1. A second bonding structure BS2 may be provided on the second structure S2. The first structure S1 and the second structure S2 may be bonded to each other by the first bonding structure BS1 and the second bonding structure BS2 and may be electrically connected to each other by at least one of various connection methods.

The first structure S1 may include a photoelectric conversion layer 10, a light transmitting layer 20, and a first wiring layer 30. The photoelectric conversion layer 10 may be disposed between the light transmitting layer 20 and the first wiring layer 30. The photoelectric conversion layer 10 may include a first substrate 100, and the first substrate 100 may include a pixel array region AR, an optical black region OBR, and a pad region PR.

The optical black region OBR may be disposed between the pixel array region AR and the pad region PR when viewed in a plan view. In some example embodiments, the optical black region OBR may surround the pixel array region AR when viewed in a plan view, and the pad region PR may surround the pixel array region AR and the optical black region OBR when viewed in a plan view. That is, when viewed in a plan view, the pixel array region AR may correspond to a central portion of the first substrate 100, and the optical black region OBR and the pad region PR may correspond to an edge portion of the first substrate 100. However, example embodiments of the present disclosure are not limited thereto. In some example embodiments, the optical black region OBR and the pad region PR may be provided on one or some of the four sides of the pixel array region AR when viewed in a plan view.

A deep device isolation pattern DTI may be provided within the first substrate 100 and may define a plurality of pixel regions PXR. The pixel regions PXR may be defined in the pixel array region AR. The deep device isolation pattern DTI may also be provided in the optical black region OBR and may define one or more reference pixel regions RPR1 and RPR2 in the optical black region OBR. In some example embodiments, the reference pixel regions RPR1 and RPR2 may include the first reference pixel region RPR1 and the second reference pixel region RPR2.

A shallow device isolation pattern STI may be provided within the first substrate 100 and may define at least one active region in each of the pixel regions PXR. In addition, the shallow device isolation pattern STI may define at least one active region in each of the first reference pixel region RPR1 and the second reference pixel region RPR2.

Photoelectric conversion regions 110 may be provided in the pixel regions PXR, respectively. In some example embodiments, a reference photoelectric conversion region 111 may be provided in the first reference pixel region RPR1. The first substrate 100 may be doped with dopants having a first conductivity type, and the photoelectric conversion regions 110 and the reference photoelectric conversion region 111 may be doped with dopants having a second conductivity type different from the first conductivity type. For example, the first conductivity type may be a P type, and the second conductivity type may be an N type. The second reference pixel region RPR2 may not include a photoelectric conversion region.

A floating diffusion region FD may be provided in a corresponding active region of each of the first reference pixel region RPR1 and the second reference pixel region RPR2, and a transfer gate TG may be provided over the corresponding active region of each of the first reference pixel region RPR1 and the second reference pixel region RPR2 with a gate dielectric layer therebetween. The different gates may be provided over the corresponding active regions of the first reference pixel region RPR1 and the second reference pixel region RPR2. The floating diffusion region FD, the transfer gate TG, and the different gates of each of the first reference pixel region RPR1 and the second reference pixel region RPR2 may have substantially the same shapes as the floating diffusion region FD, the transfer gate TG, and the different gates of each of the pixel regions PXR.

The deep device isolation pattern DTI, the shallow device isolation pattern STI, the photoelectric conversion regions 110, the reference photoelectric conversion region 111, the floating diffusion regions FD, and the transfer gates TG may be included in the photoelectric conversion layer 10.

Pixels including the photoelectric conversion regions 110 of the pixel array region AR may convert incident light into electrical signals (that is, pixel signals). A first reference pixel may include the reference photoelectric conversion region 111, the floating diffusion region FD, and the gates of the first reference pixel region RPR1, and a second reference pixel may include the floating diffusion region FD and the gates of the second reference pixel region RPR2. The second reference pixel may not include a photoelectric conversion region. The first reference pixel and the second reference pixel may be disposed in the optical black region OBR, and thus incident light may not be incident to the first reference pixel and the second reference pixel. The first reference pixel may generate a first reference charge in a dark state and may output a first noise signal, and the second reference pixel may generate a second reference charge in the dark state and may output a second noise signal. Noise components of the pixel signals output from the pixels in the pixel array region AR may be removed using the first noise signal and the second noise signal.

The light transmitting layer 20 may be provided on a second surface 100b of the first substrate 100. The light transmitting layer 20 may include a fixed charge layer 310, an anti-reflective layer 320, color filters CF1, CF2, and CF3, and micro lenses ML.

The fixed charge layer 310 may cover the second surface 100b of the first substrate 100, and the anti-reflective layer 320 may be disposed on the fixed charge layer 310.

The first circuit wiring layer 30 may be provided on a first surface 100a of the first substrate 100. The first circuit wiring layer 30 may cover the first surface 100a of the first substrate 100 and may include first interlayer insulating layers ILD1 and first wiring lines ICL1. The first wiring lines ICL1 may be provided between or through the first interlayer insulating layers ILD1. The first wiring lines ICL1 may be electrically connected with pixel transistors (e.g., a transfer transistor, a reset transistor, a source follower transistor, and/or a selection transistor) through first contact plugs and/or may electrically connect the pixel transistors.

The second structure S2 may include a second substrate 200, peripheral transistors PTR formed on the upper surface of the second substrate 200, and a second wiring layer 40 that is provided on the upper surface of the second substrate 200 and that covers the peripheral transistors PTR. The second substrate 200 may be a semiconductor substrate such as a silicon substrate, a germanium substrate, or a silicon-germanium substrate. The second wiring layer 40 may include second interlayer insulating layers ILD2 and second wiring lines ICL2 between or through the second interlayer insulating layers ILD2. The second wiring lines ICL2 may be electrically connected to the peripheral transistors PTR through second contact plugs and/or may electrically connect the peripheral transistors PTR. The second wiring lines ICL2 and the peripheral transistors PTR may constitute a peripheral circuit of the image sensor (e.g., a row decoder, a row driver, a column decoder, a timing generator, a correlated double sampler, an analog-to-digital converter, and/or an input/output buffer).

The first structure S1 may be stacked on the second structure S2, and the first structure S1 and the second structure S2 may be bonded to each other. The second wiring layer 40 may be disposed between the first circuit wiring layer 30 and the second substrate 200. In some example embodiments, the lowermost one of the first interlayer insulating layers ILD1 may be bonded to the uppermost one of the second interlayer insulating layers ILD2.

In some example embodiments, the first structure S1 may be electrically connected to the second structure S2 through one or more connecting structures 50 and 60. In some example embodiments, the connecting structures 50 and 60 may include the first connecting structure 50 and the second connecting structure 60.

The first connecting structure 50 may include a first through-electrode 51, a first filling insulation pattern 52, and a first capping pattern 53. The first through-electrode 51 may be provided in a first through-hole TH1 that penetrates the first substrate 100, the first wiring layer 30, and a portion of the second wiring layer 40 of the optical black region OBR. In an example embodiment, the first through-hole TH1 may also penetrate the fixed charge layer 310 and the anti-reflective layer 320. The first through-electrode 51 may conformally cover the inner surface of the first through-hole TH1. The first through-hole TH1 may expose a corresponding one of the first wiring lines ICL1 and a corresponding one of the second wiring lines ICL2. Accordingly, the first through-electrode 51 may be electrically connected with the corresponding one of the first wiring lines ICL1 and the corresponding one of the second wiring lines ICL2. The first filling insulation pattern 52 may be provided on the first through-electrode 51 and may fill the first through-hole TH1. The first capping pattern 53 may cover the upper surface of the first filling insulation pattern 52.

According to some example embodiments, a first connection recess CRS1 may be recessed into the first substrate 100 from the second surface 100b of the first substrate 100 of the optical black region OBR. The first connection recess CRS1 may expose a filling conductive pattern of the deep device isolation pattern DTI. In an example embodiment, the first connection recess CRS1 may penetrate the fixed charge layer 310 and the anti-reflective layer 320. The first connection recess CRS1 may be disposed on one side of the first through-hole TH1. The first through-electrode 51 may extend onto the second surface 100b of the first substrate 100 and the inner surface of the first connection recess CRS1. Accordingly, the first through-electrode 51 may be electrically connected with the filling conductive pattern of the deep device isolation pattern DTI. When the image sensor operates, a negative bias voltage may be applied to the filling conductive pattern of the deep device isolation pattern DTI through the first through-electrode 51. In an example embodiment, the first through-electrode 51 may extend further to cover the first reference pixel region RPR1 and the second reference pixel region RPR2. A portion of the first through-electrode 51 that covers the first reference pixel region RPR1 and the second reference pixel region RPR2 may function as a light blocking pattern. In an example embodiment, unlike that illustrated in FIG. 8, the portion of the first through-electrode 51 that functions as the light blocking pattern may be separated from the portion of the first through-electrode 51 that covers the inner surfaces of the first connection recess CRS1 and the first through-hole TH1.

A conductive plug 70 may fill the remaining region of the first connection recess CRS1. The conductive plug 70 may be brought into contact with the first through-electrode 51 provided in the first connection recess CRS1. In an example embodiment, the conductive plug 70 may be formed of or include a conductive material having a lower resistance than the first through-electrode 51.

As illustrated in FIG. 8, the capping insulating layer 330 may cover the first through-electrode 51 and the conductive plug 70. In the first through-hole TH1, the protective layer 350 may be provided between the first through-electrode 51 and the first filling insulation pattern 52.

A filtering pattern 80 may cover the first through-electrode 51 and the first capping pattern 53. The filtering pattern 80 may block light in a specific wavelength range. For example, the filtering pattern 80 may block ultraviolet light. For example, the filtering pattern 80 may include, but is not limited to, a blue filter.

The second connecting structure 60 may include a second through-electrode 61, a second filling insulation pattern 62, and a second capping pattern 63. The second through-electrode 61 may be provided in a second through-hole TH2 that penetrates the first substrate 100, the first wiring layer 30, and at least a portion of the second wiring layer 40 of the pad region PR. In an example embodiment, the second through-hole TH2 may additionally penetrate the fixed charge layer 310 and the anti-reflective layer 320. The second through-electrode 61 may conformally cover the inner surface of the second through-hole TH2. The second through-hole TH2 may expose a corresponding one of the second wiring lines ICL2, and thus the second through-electrode 61 may be electrically connected with the corresponding one of the second wiring lines ICL2. The second filling insulation pattern 62 may be provided on the second through-electrode 61 and may fill the second through-hole TH2. The second capping pattern 63 may cover the upper surface of the second filling insulation pattern 62.

According to some example embodiments, a second connection recess CRS2 may be recessed into the first substrate 100 from the second surface 100b of the first substrate 100 of the pad region PR. The second connection recess CRS2 may be disposed on one side of the second through-hole TH2. In an example embodiment, the second connection recess CRS2 may additionally penetrate the fixed charge layer 310 and the anti-reflective layer 320. In some example embodiments, the second through-electrode 61 may extend onto the second surface 100b of the first substrate 100 and the inner surface of the second connection recess CRS2.

A connecting pad CP may fill the remaining region of the second connection recess CRS2. The connecting pad CP may be brought into contact with the second through-electrode 61. Accordingly, the connecting pad CP may be electrically connected to the second structure S2 through the second through-electrode 61. The connecting pad CP may be used for electrical connection with an external device. In some example embodiments, the connecting pad CP may receive various signals (e.g., command signals and/or control signals) transferred from the external device, and various electrical signals generated from the image sensor may be transferred to the external device through the connecting pad CP. For example, a connector such as a bonding wire may be connected to the connecting pad CP, and the connecting pad CP may be electrically connected to the external device through the connector. In an example embodiment, the connecting pad CP may be formed of or include a conductive material having a lower resistance than the second through-electrode 61.

Each of the first through-electrode 51 and the second through-electrode 61 may be formed of or include a conductive material. For example, the first through-electrode 51 and the second through-electrode 61 may be formed of or include metal (e.g., tungsten (W), titanium (Ti), or tantalum (Ta)) and/or conductive metal nitride (e.g., titanium nitride (TiN), tantalum nitride (TaN), or tungsten nitride (WN)). In an example embodiment, the first through-electrode 51 and the second through-electrode 61 may be formed of or include the same material. Each of the first filling insulation pattern 52 and the second filling insulation pattern 62 may be formed of or include an insulating material. In an example embodiment, the first filling insulation pattern 52 and the second filling insulation pattern 62 may be formed of or include the same insulating material. Each of the first capping pattern 53 and the second capping pattern 63 may be formed of or include an insulating material. In an example embodiment, the first capping pattern 53 and the second capping pattern 63 may be formed of or include the same insulating material. As described above, the resistance of the conductive plug 70 may be lower than the resistance of the first through-electrode 51, and the resistance of the connecting pad CP may be lower than the resistance of the second through-electrode 61. In an example embodiment, the conductive plug 70 and the connecting pad CP may be formed of or include the same conductive material. For example, the conductive plug 70 and the connecting pad CP may include aluminum (Al).

A passivation layer 90 may be provided on the second surface 100b of the first substrate 100. The passivation layer 90 may cover the optical black region OBR and the pad region PR. The passivation layer 90 may cover the filtering pattern 80 and the second capping pattern 63. The passivation layer 90 may include an opening 95 that exposes the connecting pad CP. In an example embodiment, the passivation layer 90 may be formed of or include the same material as the micro lens ML.

In the above-described example embodiment, the connecting pad CP may be disposed in the second connection recess CRS2 formed within the first substrate 100. However, example embodiments of the present disclosure are not limited thereto. In some example embodiments, the connecting pad CP may be disposed in another place.

In an example embodiment, a first region R1 may vertically overlap the pixel array region AR and a portion of the optical black region OBR. A second region R2 may vertically overlap the pad region PR and the remaining portion of the optical black region OBR other than the portion of the optical black region OBR. A first bonding pattern BP1 may be provided on the first region R1. For example, the first bonding pattern BP1 may vertically overlap the pixel array region AR. In addition, a first dummy pattern DP1 may be provided on the second region R2. For example, the first dummy pattern DP1 may vertically overlap (or may be provided on) at least one of the optical black region OBR or the pad region PR.

In addition, a second bonding pattern BP2 of the second bonding structure BS2 may be bonded to the first bonding pattern BP1. A second dummy pattern DP2 of the second bonding structure BS2 may be bonded to the first dummy pattern DP1.

In an example embodiment, the first bonding structure BS1 and the second bonding structure BS2 of FIG. 8 may correspond to all of the bonding structure BS1 of FIG. 3, the bonding structure BS1a of FIG. 5, and the bonding structure BS1a of FIG. 7. In other words, the example embodiments of FIGS. 3, 5, and 7 may be applied to the semiconductor device of FIG. 8.

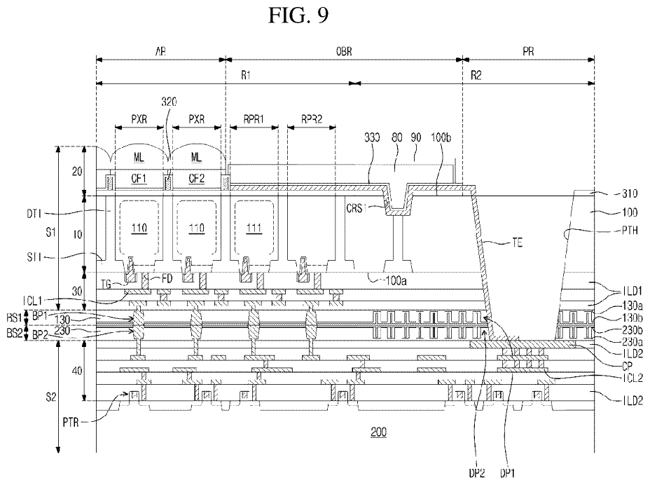

FIG. 9 is a sectional view of a semiconductor device according to an example embodiment of the present disclosure. For convenience of description, the following description will be focused on differences from the above-described example embodiments.

Referring to FIG. 9, a connecting pad CP may be disposed in a second wiring layer 40. More specifically, the connecting pad CP may be disposed in the second wiring layer 40 under a pad region PR of a first substrate 100. In an example embodiment, although not specifically shown in FIG. 9, a lateral surface and an upper surface of the connecting pad CP may be covered by the uppermost one of second interlayer insulating layers ILD2. A pad through-hole PTH may penetrate the first substrate 100, a first wiring layer 30, and a portion of the second wiring layer 40 (e.g., the uppermost second interlayer insulating layer ILD2) of the pad region PR and may expose the upper surface of the connecting pad CP.

A through-electrode TE may be disposed in the pad through-hole PTH. In an example embodiment, the through-electrode TE may be brought into contact with at least a portion of the exposed upper surface of the connecting pad CP. The through-electrode TE may extend upward along at least a portion of the inner surface of the pad through-hole PTH. In addition, the through-electrode TE may extend along a second surface 100b of the first substrate 100. Accordingly, the through-electrode TE may electrically connect the connecting pad CP to at least one of various terminals adjacent to the second surface 100b of the first substrate 100. For example, the through-electrode TE may extend onto the inner surface of a first connection recess CRS1 and may be connected with a filling conductive pattern of a deep device isolation pattern DTI. In an example embodiment, for a light blocking function, the through-electrode TE may extend to cover a first reference pixel region RPR1 and a second reference pixel region RPR2.

As illustrated, in this example embodiment, the second connection recess CRS2, the first connecting structure 50, and the second connecting structure 60 of FIG. 8 may be omitted. However, example embodiments of the present disclosure are not limited thereto. In some example embodiments, at least one of the first connecting structure 50 or the second connecting structure 60 may be applied to an image sensor according to this example embodiment.

In an example embodiment, a first region R1 may vertically overlap a pixel array region AR and a portion of an optical black region OBR. A second region R2 may vertically overlap the pad region PR and the remaining portion of the optical black region OBR other than the portion of the optical black region OBR. A first bonding pattern BP1 may be provided on the first region R1. For example, the first bonding pattern BP1 may vertically overlap the pixel array region AR. In addition, a first dummy pattern DP1 may be provided on the second region R2. For example, the first dummy pattern DP1 may vertically overlap (or may be provide on) at least one of the optical black region OBR or the pad region PR.

In addition, a second bonding pattern BP2 of a second bonding structure BS2 may be bonded to the first bonding pattern BP1. A second dummy pattern DP2 of the second bonding structure BS2 may be bonded to the first dummy pattern DP1. Accordingly, a first structure S1 and a second structure S2 may be electrically connected to each other through the first bonding structure BS1 and the second bonding structure BS2.

In an example embodiment, the first bonding structure BS1 and the second bonding structure BS2 of FIG. 9 may correspond to all of the bonding structure BS1 of FIG. 3, the bonding structure BS1a of FIG. 5, and the bonding structure BS1a of FIG. 7. In other words, the example embodiments of FIGS. 3, 5, and 7 may be applied to the semiconductor device of FIG. 9.

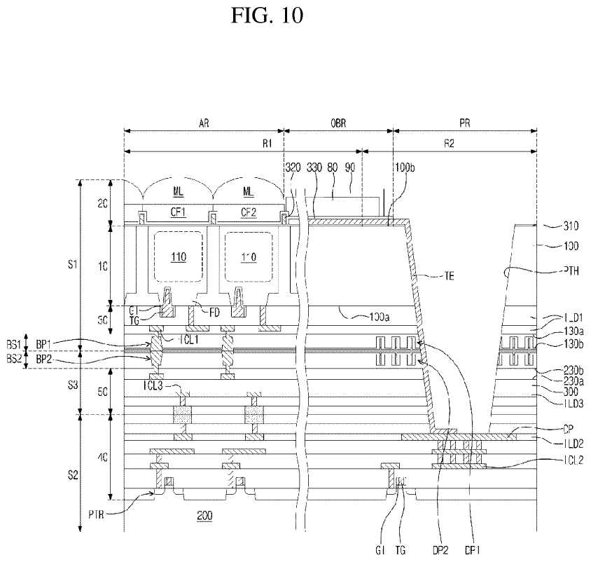

FIG. 10 is a sectional view of a semiconductor device according to an example embodiment of the present disclosure. For convenience of description, the following description will be focused on differences from the above-described example embodiments.

Referring to FIG. 10, the semiconductor device according to an example embodiment of the present disclosure may include a first structure S1, a second structure S2, and a third structure S3. The third structure S3 may be disposed between the first structure S1 and the second structure S2.

The first structure S1 may include a light transmitting layer 20, a photoelectric conversion layer 10, and a first circuit wiring layer 30. The light transmitting layer 30 may be the same as the light transmitting layer 30 of FIG. 9. The photoelectric conversion layer 10 may include the first substrate 100, the photoelectric conversion region 110, the deep device isolation pattern DTI, the shallow device isolation pattern STI, the transfer gates TG, and the gates and the source/drain regions of the logic transistors of FIGS. 8 and 9. The first circuit wiring layer 30 may include first interlayer insulating layers ILD1 and first wiring lines ICL1.

The second structure S2 may include a second substrate 200 and a second circuit wiring layer 40 on the second substrate 200. The second structure S2 may be substantially the same as the second structure S2 of FIG. 9. However, the second structure S2 may further include second bonding pads provided in the uppermost one of second interlayer insulating layers ILD2.

The third structure S3 may include a third substrate 300, gates on the third substrate 300, third interlayer insulating layers ILD3, and third wiring lines ICL3 provided on the third substrate 300. The third substrate 300 may be a semiconductor substrate. Each of the gates may be disposed on the third substrate 300 with a gate dielectric layer therebetween. The source/drain regions (not illustrated) may be provided within the third substrate 300 so as to be located on the opposite sides of each of the gates.

The third circuit wiring layer 50 may include the third wiring lines ICL3 and the third interlayer insulating layers ILD3.

According to an example embodiment, the first structure S1 and the third structure S3 may be bonded to each other by a copper-to-copper bonding method, and the third structure S3 and the second structure S2 may also be bonded to each other by a copper-to-copper bonding method.

For example, a first bonding pattern BS1 may be provided on the first structure S1. A second bonding pattern BS2 may be provided on the third structure S3. A first bonding pattern BP1 may be provided on a first region R1 of the first substrate 100. For example, the first bonding pattern BP1 may vertically overlap (or may be provided on) a pixel array region AR. In addition, a first dummy pattern DP1 may be provided on a second region R2 of the first substrate 100. For example, the first dummy pattern DP1 may vertically overlap (or may be provided on) at least one of an optical black region OBR or a pad region PR.

In addition, a second bonding pattern BP2 of the second bonding structure BS2 may be bonded to the first bonding pattern BP1. A second dummy pattern DP2 of the second bonding structure BS2 may be bonded to the first dummy pattern DP1. Accordingly, the first structure S1 and the third structure S3 may be electrically connected to each other through the first bonding structure BS1 and the second bonding structure BS2.

In an example embodiment, the first bonding structure BS1 and the second bonding structure BS2 of FIG. 10 may correspond to all of the bonding structure BS1 of FIG. 3, the bonding structure BS1a of FIG. 5, and the bonding structure BS1a of FIG. 7. In other words, the example embodiments of FIGS. 3, 5, and 7 may be applied to the semiconductor device of FIG. 10.

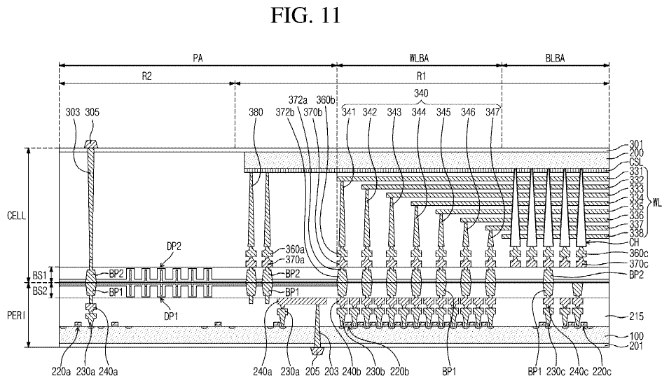

FIG. 11 is a sectional view of a semiconductor device according to an example embodiment of the present disclosure. For convenience of description, the following description will be focused on differences from the above-described example embodiments.

Referring to FIG. 11, the semiconductor device according to an example embodiment of the present disclosure may be a memory device having a chip to chip (C2C) structure. The C2C structure may mean manufacturing an upper chip including a cell region CELL on a first substrate 100, manufacturing a lower chip including a peripheral circuit region PERI on a second substrate 200 different from the first substrate 100, and then connecting the upper chip and the lower chip to each other by a bonding method. For example, the bonding method may mean a method of electrically connecting a first bonding pattern BP1 formed on the uppermost metal layer of the upper chip and a second bonding pattern BP2 formed on the uppermost metal layer of the lower chip. For example, when the first bonding pattern BP1 and the second bonding pattern BP2 are formed of or include copper (Cu), the bonding method may be a Cu-Cu bonding method. The first bonding pattern BP1 and the second bonding pattern BP2 may also be formed of or include aluminum (Al) or tungsten (W).

Each of the peripheral circuit region PERI and the cell region CELL may include an external pad bonding region PA, a word line bonding region WLBA, and a bit line bonding region BLBA.

The peripheral circuit region PERI may include the first substrate 100, an interlayer insulating layer 215, a plurality of circuit devices 220a, 220b, and 220c formed on the first substrate 100, a first metal layer 230a, 230b, and 230c connected with the plurality of circuit devices 220a, 220b, and 220c, and a second metal layer 240a, 240b, and 240c formed on the first metal layer 230a, 230b, and 230c. In an example embodiment, the first metal layer 230a, 230b, and 230c may be formed of tungsten, which has relatively high resistance, and the second metal layer 240a, 240b, and 240c may be formed of copper, which has relatively low resistance.

In this specification, only the first metal layer 230a, 230b, and 230c and the second metal layer 240a, 240b, and 240c are illustrated and described. However, example embodiments of the present disclosure is not limited thereto, and one or more metal layers may be further formed on the second metal layer 240a, 240b, and 240c. At least some of the metal layers formed on the second metal layer 240a, 240b, and 240c may be formed of or include aluminum, which has a higher resistance than copper of which the second metal layer 240a, 240b, and 240c is formed.

The interlayer insulating layer 215 may be disposed on the first substrate 100 to cover the plurality of circuit devices 220a, 220b, and 220c, the first metal layer 230a, 230b, and 230c, and the second metal layer 240a, 240b, and 240c and may include an insulating material such as silicon oxide or silicon nitride.

The first bonding pattern BP1 may be formed on the second metal layer 240b of the word line bonding region WLBA. In the word line bonding region WLBA, the first bonding pattern BP1 of the peripheral circuit region PERI may be electrically connected with the second bonding pattern BP2 of the cell region CELL by a bonding method. The first bonding pattern BP1 and the second bonding pattern BP2 may be formed of or include aluminum, copper, tungsten, or a combination thereof.

The cell region CELL may provide at least one memory block. The cell region CELL may include the second substrate 200 and a common source line CSL. On the second substrate 200, a plurality of word lines WL (331 to 338) may be stacked in a direction perpendicular to the upper surface of the second substrate 200.

In the bit line bonding region BLBA, a channel structure CH may extend in the direction perpendicular to the upper surface of the second substrate 200 and may penetrate the word lines WL. The channel structure CH may include a data storage layer, a channel layer, and a filling insulation layer, and the channel layer may be electrically connected with a first metal layer 360c and a second metal layer 370c. For example, the first metal layer 360c may be a bit line contact, and the second metal layer 370c may be a bit line.

The region where the channel structure CH and the first metal layers (e.g., bit lines) 360c are disposed may be defined as the bit line bonding region BLBA. The first metal layers (e.g., bit lines) 360c may be electrically connected with the circuit devices 220c in the peripheral circuit region PERI in the bit line bonding region BLBA. For example, the first metal layers (e.g., bit lines) 360c may be connected with the second bonding pattern BP2 in the peripheral circuit region PERI, and the second bonding pattern BP2 may be connected with the first bonding pattern BP1 connected to the circuit devices 220c.

In the word line bonding region WLBA, the word lines WL may extend in a direction parallel to the upper surface of the second substrate 200 and perpendicular to the extension direction of the first metal layers (e.g., bit lines) 360c and may be connected with a plurality of cell contact plugs 340 (341 to 347). The word lines WL and the cell contact plugs 340 may be connected to each other at pads that at least some of the word lines WL extend to different lengths to provide. A first metal layer 360b and a second metal layer 370b may be sequentially connected to the upper surfaces of the cell contact plugs 340 connected to the word lines WL. The cell contact plugs 340 may be connected with the peripheral circuit region PERI through the second bonding pattern BP2 of the cell region CELL and the first bonding pattern BP1 of the peripheral circuit region PERI in the word line bonding region WLBA.

The cell contact plugs 340 may be electrically connected with the circuit devices 220b in the peripheral circuit region PERI. A common source line contact plug 380 may be disposed in the external pad bonding region PA. The common source line contact plug 380 may be formed of or include a conductive material such as metal, metal compound, or poly silicon. In addition, the common source line contact plug 380 may be electrically connected with the common source line CSL. A first metal layer 360a and a second metal layer 370a may be sequentially stacked on the common source line contact plug 380. For example, the region where the common source line contact plug 380, the first metal layer 360a, and the second metal layer 370a are disposed may be defined as the external pad bonding region PA.

Meanwhile, input/output pads 205 and 305 may be disposed in the external pad bonding region PA. As illustrated in FIG. 11, a lower insulating layer 201 that covers the lower surface of the first substrate 100 may be formed on the bottom of the first substrate 100, and the first input/output pad 205 may be formed on the lower insulating layer 201. The first input/output pad 205 may be connected with at least one of the plurality of circuit devices 220a, 220b, and 220c disposed in the peripheral circuit region PERI through a first input/output contact plug 203 and may be separated from the first substrate 100 by the lower insulating layer 201. In addition, a lateral insulating layer may be disposed between the first input/output contact plug 203 and the first substrate 100 and may electrically isolate the first input/output contact plug 203 and the first substrate 100 from each other.

An upper insulating layer 301 that covers the upper surface of the second substrate 200 may be formed on the top of the second substrate 200, and the second input/output pad 305 may be disposed on the upper insulating layer 301. The second input/output pad 305 may be connected with at least one of the plurality of circuit devices 220a, 220b, and 220c disposed in the peripheral circuit region PERI through a second input/output contact plug 303.

In an example embodiment, the bit line bonding region BLBA, the word line bonding region WLBA, and a portion of the external pad bonding region PA may overlap a first region R1, and another portion of the external pad bonding region PA other than the portion of the external pad bonding region PA may overlap a second region R2. A second bonding pattern BP2 may be disposed on the second substrate 200 in the first region R1, and a second dummy pattern DP2 may be disposed on the second substrate 200 in the second region R2. In addition, a first bonding pattern BP1 may be disposed on the first substrate 100 in the first region R1, and a first dummy pattern DP1 may be disposed on the first substrate 100 in the second region R2. Furthermore, the first bonding pattern BP1 may be bonded to the second bonding pattern BP2, and the first dummy pattern DP1 may be bonded to the second dummy pattern DP2.

In an example embodiment, the first bonding structure BS1 and the second bonding structure BS2 of FIG. 11 may correspond to all of the bonding structure BS1 of FIG. 3, the bonding structure BS1a of FIG. 5, and the bonding structure BS1a of FIG. 7. In other words, the example embodiments of FIGS. 3, 5, and 7 may be applied to the semiconductor device of FIG. 11.

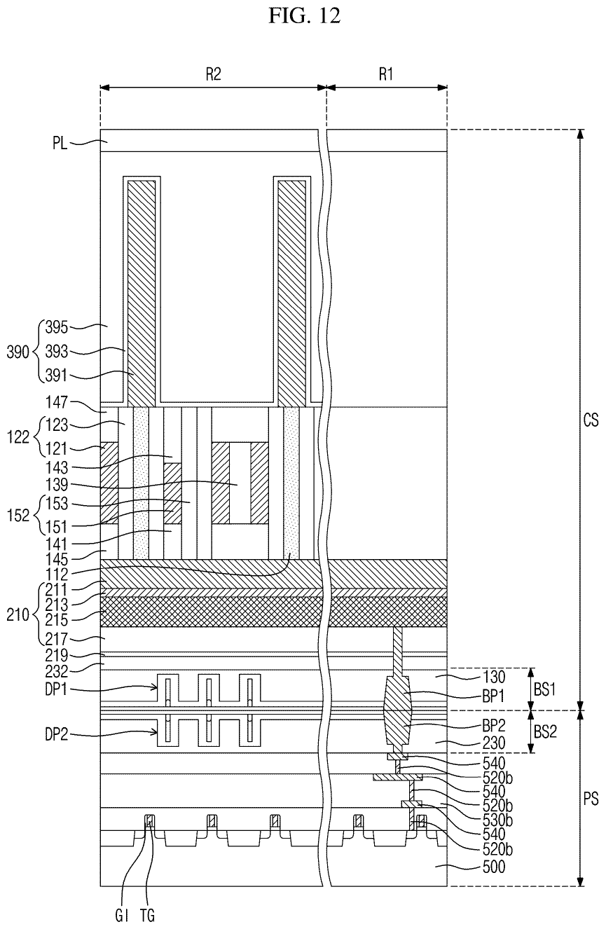

FIG. 12 is a sectional view of a semiconductor device according to an example embodiment of the present disclosure. For convenience of description, the following description will be focused on differences from the above-described example embodiments.

Referring to FIG. 12, the semiconductor device according to an example embodiment of the present disclosure may include memory cells including a vertical channel transistor (VCT). The vertical channel transistor may refer to a transistor in which a semiconductor pattern extends in a direction perpendicular to the upper surface of a semiconductor substrate. In an example embodiment, the semiconductor device may include a vertical semiconductor pattern 112, a bit line 210, a first gate structure 122, a first capping pattern 141, a second capping pattern 143, a third capping pattern 145, a fourth capping pattern 147, a second gate structure 152, a capacitor 390, and a passivation layer PL.

In an example embodiment, a cell array structure CS may include a first bonding structure BS1. The first bonding structure BS1 may be provided on a dielectric layer 232. A peripheral circuit structure PS may include a second bonding structure BS2. The second bonding structure BS2 may be provided on a third interlayer insulating layer 530b.

A first bonding pattern BP1 may be electrically connected with a first gate electrode 121, a second gate electrode 151, and the bit lines 210 through first contact plugs 520a. The first bonding pattern BP1 may be in direct contact with and bonded to a second bonding pattern BP2 of the peripheral circuit structure PS. The peripheral circuit structure PS may include a core and peripheral circuits formed on a third substrate 500. Here, the core may be a circuit to which memory cells of a semiconductor memory device are connected, and the peripheral circuits may refer to other circuits. The core and the peripheral circuits may include row and column decoders, sense amplifiers (SA), and control logics.

The second bonding pattern BP2 may be provided on the uppermost layer among the third interlayer insulating layer 530b of the peripheral circuit structure PS. The second bonding pattern BP2 may be electrically connected with the core and the peripheral circuits of the semiconductor memory device through peripheral wires 540 and second contact plugs 520b.

In an example embodiment, the first bonding pattern BP1 may be provided on a first region R1, and a first dummy pattern DP1 may be provided on a second region R2. The first bonding pattern BP1 may be bonded to the second bonding pattern BP2, and the first dummy pattern DP1 may be bonded to a second dummy pattern DP2. In other words, the peripheral circuit structure PS and the cell array structure CS may be electrically connected through bonding of the first bonding structure BS1 and the second bonding structure BS2.

In an example embodiment, the first bonding structure BS1 and the second bonding structure BS2 of FIG. 12 may correspond to all of the bonding structure BS1 of FIG. 3, the bonding structure BS1a of FIG. 5, and the bonding structure BS1a of FIG. 7. In other words, the example embodiments of FIGS. 3, 5, and 7 may be applied to the semiconductor device of FIG. 12.

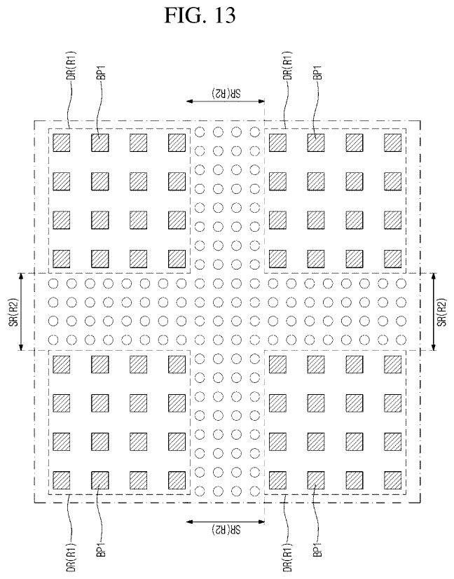

FIG. 13 is a plan view of a semiconductor device according to an example embodiment of the present disclosure. For convenience of description, the following description will be focused on differences from the above-described example embodiments.

Referring to FIG. 13, the substrate 100 (refer to FIG. 3) of the semiconductor device according to an example embodiment of the present disclosure may include a die region DR and a scribe region SR. The die region DR may be a region on the substrate 100 (refer to FIG. 3) where circuit devices are formed. The scribe region SR, which surrounds the die region DR, may be a region that is cut off from the substrate 100 (refer to FIG. 3) through a sawing process and disappears.

In an example embodiment, the die region DR may correspond to the first region R1 of FIG. 3, and the scribe region SR may correspond to the second region R2 of FIG. 3. For example, the first bonding structure BS1 (refer to FIG. 3) may be formed on the die region DR and the scribe region SR of the substrate 100 (refer to FIG. 3). In addition, the first bonding pattern BP1 may be provided on the die region DR of the substrate 100 (refer to FIG. 3). The first dummy pattern DP1 may be provided on the scribe region SR of the substrate 100 (refer to FIG. 3).

In an example embodiment, the die region DR and the scribe region SR of FIG. 13 may correspond to the first region R1 and the second region R2 of FIG. 3, the first region R1 and the second region R2 of FIG. 5, or the first region R1 and the second region R2 of FIG. 7. In other words, the example embodiments of FIGS. 3, 5, and 7 may be applied to the semiconductor device of FIG. 13.

Meanwhile, a semiconductor device manufacturing method according to some example embodiments of the present disclosure will be described below.

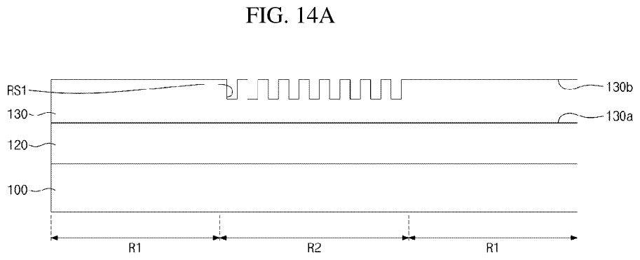

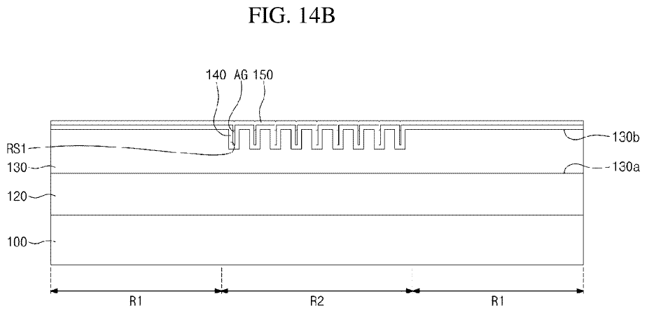

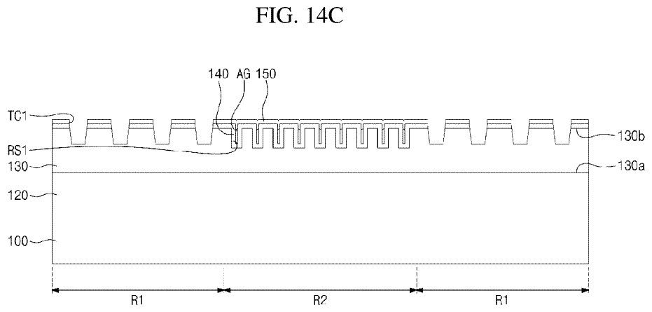

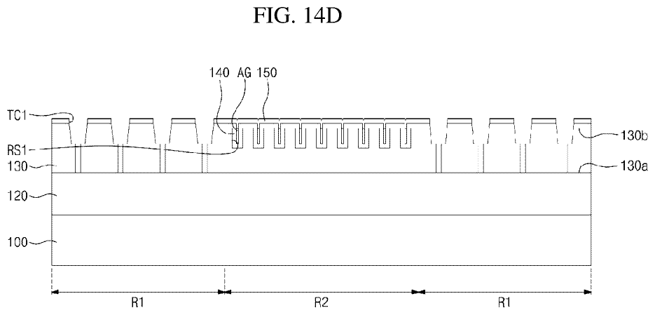

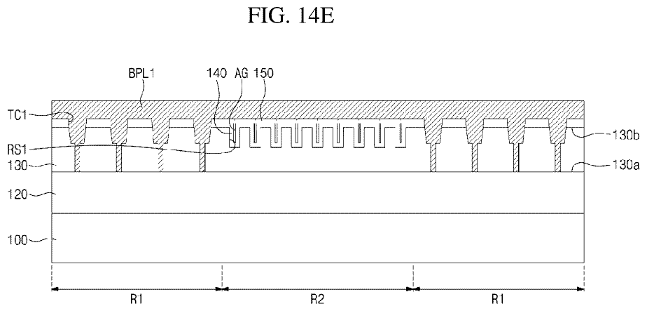

FIGS. 14A to 14E are sectional views illustrating the semiconductor device manufacturing method according to an example embodiment of the present disclosure.

Referring to FIGS. 14A to 14E, the substrate 100 may be prepared. The first insulating layer 130 may be formed on the substrate 100. The first insulating layer 130 may have the first surface 130a that makes contact with the substrate 100 and the second surface 130b that is opposite the first surface 130a. The first insulating layer 130 may be formed, for example, by a deposition process or an oxidation process.

Next, the first recess RS1 may be formed from the second surface 130b of the first insulating layer 130. The first recess RS1 may be formed on the second region R2 of the substrate 100. The formation of the first recess RS1 may be performed, for example, through a patterning process.

Then, the first insulating liner layer 140 and the second insulating liner layer 150 may be sequentially formed on the first insulating layer 130. More specifically, the first insulating liner layer 140 and the second insulating liner layer 150 may be formed on the upper surface of the first insulating layer 130 and the inner surface of the first recess RS1. In the process of forming the first insulating liner layer 140 and the second insulating liner layer 150, the air gap AG may be defined between the first insulating liner layer 140 and the second insulating liner layer 150.

In an example embodiment, the second insulating liner layer 150 may have a higher removal rate than the first insulating liner layer 140. For example, the second insulating liner layer 150 may be formed of or include a material having a higher removal rate than the first insulating liner layer 140. For example, the second insulating liner layer 150 may be formed of or include silicon oxide (SiOₓ), and the first insulating liner layer 140 may be formed of silicon carbon nitride (SiCₓN_{y}), silicon oxy nitride (SiOₓN_{y}), or a combination thereof.

The first insulating liner layer 140 and the second insulating liner layer 150 may be formed, for example, by a deposition process or an oxidation process.

After that, as illustrated in FIG. 14C, the first trench TC1 may be formed. The first trench TC1 may be formed by continuously making the second insulating liner layer 150 and the first insulating liner layer 140 subject to patterning after the formation of the second insulating liner layer 150 is performed. The first trench TC1 may be formed on the first region R1 of the substrate 100.

After the first trench TC1 is formed, an additional patterning process may be performed to form the first via hole VH1. The first via hole VH1 may be formed by making the bottom surface of the first trench TC1 subject to patterning. Accordingly, the first via hole VH1 may be formed under the first trench TC1.

A first bonding conductive layer BPL1 may be formed in the first trench TC1 and the first via holes VH1. The first bonding conductive layer BPL1 may be formed on the second insulating liner layer 150. The first bonding conductive layer BPL1 may fill the first trench TC1. The first bonding conductive layer BPL1 may be formed, for example, through an electroplating process or a deposition process.

Referring again to FIG. 3, a chemical mechanical polishing process may be performed to polish the first bonding conductive layer BPL1, the second insulating liner layer 150, and a portion of the first insulating liner layer 140. Accordingly, the surface of the first insulating liner layer 140 may be exposed, and the first dummy pattern DP1 and the first bonding pattern BP1 may be formed. In addition, a portion of the first bonding conductive layer BPL1 that fills the first via hole VH1 may be used as the first via pattern VP1.

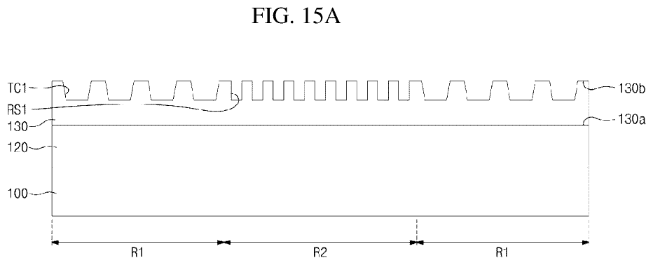

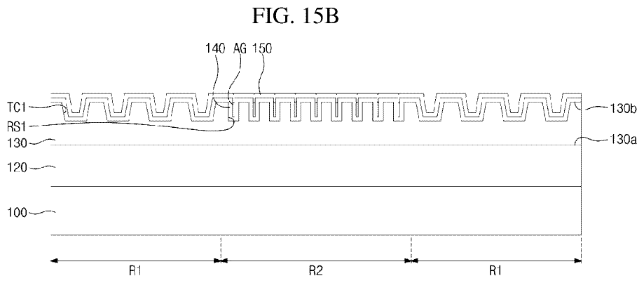

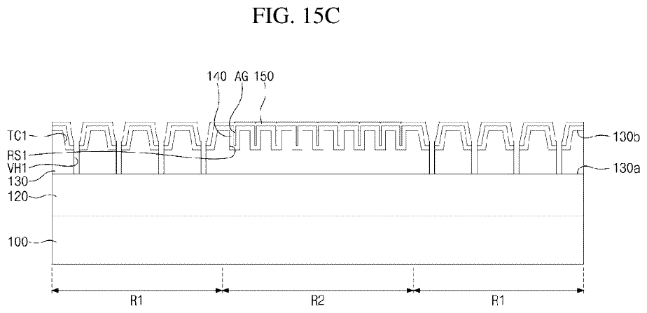

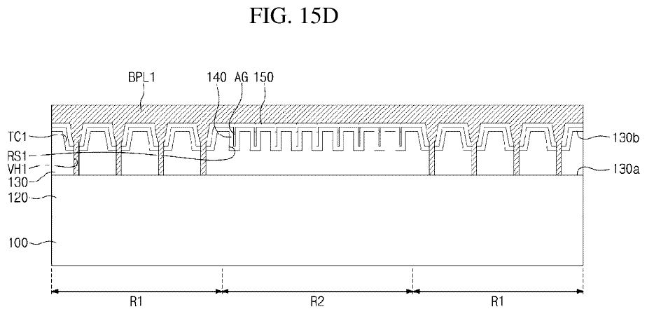

FIGS. 15A to 15D are sectional views illustrating a semiconductor device manufacturing method according to an example embodiment of the present disclosure. For convenience of description, the following description will be focused on differences from the above-described example embodiments.

Referring to FIGS. 15A to 15D, the first trench TC1 may be simultaneously formed together with the first recess RS1. The first trench TC1 may be formed on the first region R1, and the first recess RS1 may be formed on the second region R2.

Next, the first insulating liner layer 140 and the second insulating liner layer 150 may be sequentially formed on the second surface 130b of the first insulating layer 130. At this time, the first insulating liner layer 140 and the second insulating liner layer 150 may be conformally formed on the inner surface of the first recess RS1 and the inner surface of the first trench TC1.

Then, a patterning process may be performed to etch the first insulating liner layer 140 and the second insulating liner layer 150. Accordingly, an empty space exposing a portion of the bottom surface of the first trench TC1 and the first via hole VH1 may be formed.

After that, the first bonding conductive layer BPL1 may fill the empty space and the first via hole VH1.

Referring again to FIG. 5, a chemical mechanical polishing process may be performed to polish the first bonding conductive layer BPL1, the second insulating liner layer 150, and a portion of the first insulating liner layer 140. Accordingly, the surface of the first insulating liner layer 140 may be exposed, and the first dummy pattern DP1 and the first bonding pattern BP1a may be formed. In addition, a portion of the first bonding conductive layer BPL1 that fills the first via hole VH1 may be used as the first via pattern VP1.

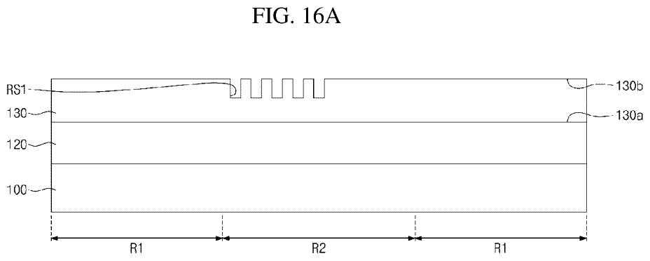

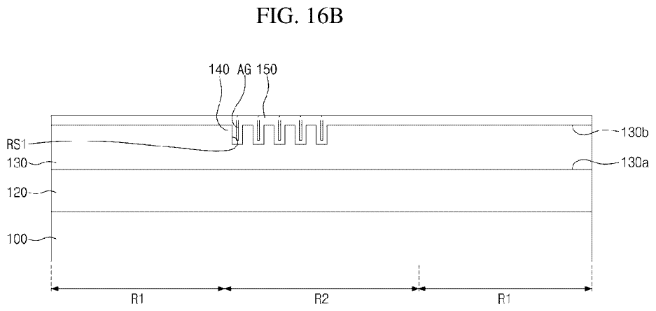

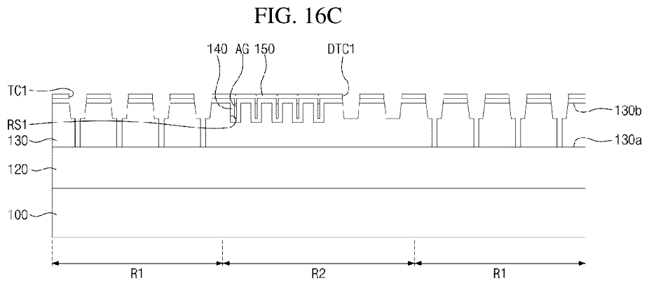

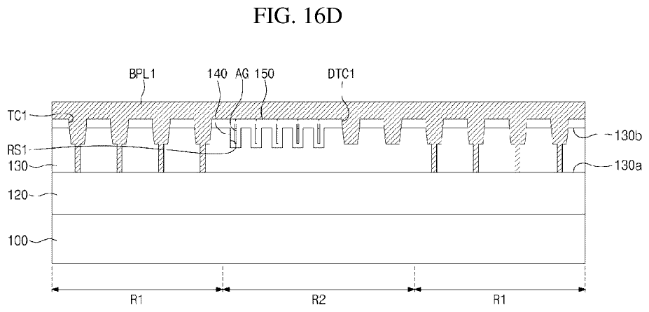

FIGS. 16A to 16D are sectional views illustrating a semiconductor device manufacturing method according to an example embodiment of the present disclosure. For convenience of description, the following description will be focused on differences from the above-described example embodiments.

Referring to FIGS. 16A to 16D, a patterning process may be performed such that the first recess RS1 is formed on a portion of the second region R2 of the substrate 100. Next, the first insulating liner layer 140 and the second insulating liner layer 150 may be sequentially formed on the first insulating layer 130. In the process of forming the first insulating liner layer 140 and the second insulating liner layer 150, the air gap AG may be defined between the first insulating liner layer 140 and the second insulating liner layer 150. The first insulating liner layer 140 and the second insulating liner layer 150 may be formed, for example, by a deposition process or an oxidation process.

Then, as illustrated in FIG. 16C, the first trench TC1 may be formed. The first trench TC1 may be formed by continuously making the second insulating liner layer 150 and the first insulating liner layer 140 subject to patterning after the formation of the second insulating liner layer 150 is performed. The first trench TC1 may be formed on the first region R1 of the first substrate 100.

The first dummy trench DTC1 may be additionally formed on the second region R2 at the same time that the first trench TC1 is formed. The first dummy trench DTC1 may be formed on a region of the second region R2 that does not overlap the first recess RS1. The first dummy trench DTC1 may have substantially the same shape and structure as the first trench TC1.

After that, an additional patterning process may be performed to form the first via hole VH1. The first via hole VH1 may be formed by making the bottom surface of the first trench TC1 subject to patterning. Accordingly, the first via hole VH1 may be formed under the first trench TC1.

The first bonding conductive layer BPL1 may be formed in the first trench TC1, the first dummy trench DTC1, and the first via holes VH1. Although not illustrated, the first bonding conductive layer BPL1 may be formed on a sacrificial liner layer. The first bonding conductive layer BPL1 may fill the first trench TC1 and the first dummy trench DTC1.

Referring again to FIG. 7, a chemical mechanical polishing process may be performed to polish the first bonding conductive layer BPL1, the second insulating liner layer 150, and a portion of the first insulating liner layer 140. Accordingly, the surface of the first insulating liner layer 140 may be exposed, and the first dummy pattern DP1, the first dummy bonding pattern DBP1, and the first bonding pattern BP1 may be formed. In addition, a portion of the first bonding conductive layer BPL1 that fills the first via hole VH1 may be used as the first via pattern VP1.

The semiconductor device according to the above example embodiment of the present disclosure may improve the flatness of the bonding portion.

The semiconductor device manufacturing method according to the above example embodiment of the present disclosure may improve the accuracy of the bonding process.

According to an example embodiment, a method for manufacturing a semiconductor device includes forming a first insulating layer on a substrate including a first region and a second region, forming a first recess in the first insulating layer on the second region, forming a first insulating liner layer on an upper surface of the first insulating layer and an inner surface of the first recess, forming a first trench in the first insulating layer on the first region, and forming a first bonding pattern in the first trench, wherein the first insulating liner layer remains on the upper surface of the first insulating layer after the forming of the first bonding pattern.

The method may further include forming a second insulating liner layer on the first insulating liner layer before the forming of the first bonding pattern, and a first removal rate of the first insulating liner layer may be greater than a second removal rate of the second insulating liner layer.

The forming of the first trench may include forming the first trench by continuously making the second insulating liner layer, the first insulating liner layer, and the first insulating layer subject to patterning after the forming of the second insulating liner layer.

The first trench may be simultaneously formed together with the first recess, and the first insulating liner layer and the second insulating liner layer may also be formed on an inner surface of the first trench. The forming of the first bonding pattern may include forming an empty space to expose a portion of a bottom surface of the first trench, by etching the first insulating liner layer and the second insulating liner layer in the first trench, forming a first bonding conductive layer that fills the empty space, and polishing the first bonding conductive layer to expose the first insulating liner layer.

The method may further include forming a first dummy trench in the first insulating layer on the second region and forming a first dummy bonding pattern in the first dummy trench.

The first dummy trench may be simultaneously formed together with the first trench, and the first dummy bonding pattern may be simultaneously formed together with the first bonding pattern.

The forming of the first bonding pattern may include forming, on the second insulating liner layer, a first bonding conductive layer that fills the first trench and polishing the first bonding conductive layer by a chemical mechanical polishing process to expose the first insulating liner layer.

The method may further include forming a first via hole under the first trench by making a bottom surface of the first trench subject to patterning before the forming of the first bonding pattern.

The first bonding conductive layer may fill the first trench and the first via hole, and a portion of the first bonding conductive layer that fills the first via hole may be used as a first via pattern.

The first bonding pattern may include copper.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A semiconductor device comprising:
a first substrate including a first region and a second region;
a first insulating layer on the first substrate, the first insulating layer having a first surface and a second surface, the first surface being adjacent to the first substrate and the second surface being opposite the first surface, the first insulating layer including a first trench on the first region and a first recess on the second region, the first recess being recessed from the second surface of the first insulating layer;
a first insulating liner layer on the second surface of the first insulating layer, the first insulating liner layer extending onto an inner surface of the first recess; and
a first bonding pattern in the first trench.

2. The semiconductor device of claim 1, wherein a level of an upper surface of the first bonding pattern is at a same level as an upper surface of the first insulating liner layer on the first region.

3. The semiconductor device of claim 1, wherein the first trench vertically extends to penetrate the first insulating liner layer.

4. The semiconductor device of claim 1, wherein
the first insulating liner layer extends to cover an inner surface of the first trench, and
the first bonding pattern penetrates the first insulating liner layer on a bottom surface of the first trench.

5. The semiconductor device of claim 1, further comprising:
a second insulating liner layer on the first insulating liner layer,
wherein the second insulating liner layer extends into the first recess.

6. The semiconductor device of claim 5, wherein
the second insulating liner layer extends to cover the first insulating liner layer in the first trench, and
the first bonding pattern penetrates the second insulating liner layer on a bottom surface of the first trench.

7. The semiconductor device of claim 1, wherein the first recess includes an air gap defined therein, lower and side boundaries of the air gap being surrounded by the first insulating liner layer.

8. The semiconductor device of claim 1, further comprising:
a first via pattern in the first insulating layer and connected to a lower surface of the first bonding pattern.

9. The semiconductor device of claim 1, wherein a level of a bottom surface of the first bonding pattern is higher than or at a same as a level of a bottom surface of the first recess.

10. The semiconductor device of claim 1, further comprising:
a first dummy bonding pattern in a first dummy trench, the first insulating layer including the first dummy trench defined therein on the second region.

11. The semiconductor device of claim 10, wherein the first dummy bonding pattern is a same material as the first bonding pattern.

12. The semiconductor device of claim 1, wherein the first bonding pattern includes copper (Cu).

13. The semiconductor device of claim 1, wherein the first insulating liner layer includes silicon oxide (SiOₓ), silicon nitride (SiNₓ), silicon oxy nitride (SiOₓN_{y}), silicon carbon nitride (SiCₓN_{y}), or a combination thereof.

14. The semiconductor device of claim 1, wherein
the first recess includes a plurality of first recesses, the first insulating layer including the first recesses defined on the second region, and
the first recesses are in one or two directions parallel to the second surface of the first insulating layer when viewed in a plan view.

15. The semiconductor device of claim 1, wherein the first recess has a circular shape, an elliptical shape, a polygonal shape, or a line shape when viewed in a plan view.

16. The semiconductor device of claim 5, wherein
the first bonding pattern penetrates the first insulating liner layer and the second insulating liner layer, and
a width of a bottom surface of the first trench is greater than a width of a bottom surface of the first recess.

17. The semiconductor device of claim 1, further comprising:
a second substrate;
a second insulating layer on the second substrate, the second insulating layer having a third surface and a fourth surface, the third surface being adjacent to the second substrate and the fourth surface being opposite the third surface, the second insulating layer including a second trench and a second recess, the second recess being recessed from the fourth surface of the second insulating layer;
a third insulating liner layer on the fourth surface of the second insulating layer, the third insulating liner layer extending onto an inner surface of the second recess; and
a second bonding pattern in the second trench,
wherein the first bonding pattern and the second bonding pattern are bonded to each other.

18. A semiconductor device comprising:
a first substrate including a first region and a second region;
a first insulating layer on the first substrate, the first insulating layer having a first surface and a second surface, the first surface being adjacent to the first substrate and the second surface being opposite the first surface, the first insulating layer including a first trench on the first region and a first recess on the second region, the first recess being recessed on the second region from the second surface of the first insulating layer;
a first insulating liner layer on the second surface of the first insulating layer, the first insulating liner layer extending onto an inner surface of the first recess;
a first bonding pattern in the first trench;
a second substrate;
a second insulating layer on the second substrate, the second insulating layer having a third surface and a fourth surface, the third surface being adjacent to the second substrate and the fourth surface being opposite the third surface, the second insulating layer including a second trench and a second recess, the second recess being recessed from the fourth surface of the second insulating layer;
a third insulating liner layer on the fourth surface of the second insulating layer, the third insulating liner layer extending onto an inner surface of the second recess; and
a second bonding pattern in the second trench,
wherein the first bonding pattern and the second bonding pattern are bonded to each other, and
wherein the first insulating liner layer and the third insulating liner layer are bonded to each other.

19. The semiconductor device of claim 18, further comprising:
a first device layer between the first substrate and the first insulating layer; and
a second device layer between the second substrate and the second insulating layer,
wherein the first device layer is electrically connected with the first bonding pattern, and
wherein the second device layer is electrically connected with the second bonding pattern.

20. A semiconductor device comprising:
a first structure; and
a second structure bonded to the first structure,
wherein the first structure includes
a first substrate including a pixel array region, a pad region on one side of the pixel array region, and an optical black region between the pixel array region and the pad region,
a first bonding pattern vertically overlapping the pixel array region, the first bonding pattern being in a first trench defined in a first insulating layer, and
a first dummy pattern vertically overlapping at least one of the optical black region or the pad region, and
wherein the second structure includes
a second substrate,
a second bonding pattern bonded to the first bonding pattern, and
a second dummy pattern bonded to the first dummy pattern.
